(19) United States
(12) Patent Application Publication
(10) Pub. No.: US 2018/0224741 A1
(43) Pub. Date: Aug. 9, 2018

(54) COMPOSITIONS AND METHODS FOR FORMING A PIXEL-DEFINING LAYER

(71) Applicant: Rohm and Haas Electronic Materials LLC, Marlborough, MA (US)

(72) Inventors: Peng-Wei Chuang, Santa Clara, CA (US); Deyan Wang, Hudson, MA (US); Jibin Sun, Menlo Park, CA (US); Peter Trefonas, III, Medway, MA (US); Kathleen M. O'Connell, Cumberland, RI (US)

(21) Appl. No.: 15/747,897

(22) PCT Filed: Jul. 11, 2016
(86) PCT No.: PCT/US16/41681

§ 371 Date: Jan. 26, 2018

Related U.S. Application Data
(60) Provisional application No. 62/201,807, filed on Aug. 6, 2015.

(51) Int. Cl. G03F 7/00; G03F 7/004; G03F 7/037; G03F 7/16; G03F 7/20; G03F 7/32; G03F 7/40; H01L 27/32; H01L 51/56; H01L 51/52; C08F 220/18; C09D 133/08; C08G 61/12; C09D 165/00

(52) U.S. Cl. CPC G03F 7/0007; C08G 2261/3324; G03F 7/037; G03F 7/162; G03F 7/168; G03F 7/2004; G03F 7/327; G03F 7/40; H01L 27/3246; H01L 51/56; H01L 51/5221; C08F 220/18; C09D 133/08; C08G 61/124; C09D 165/00; C08F 2800/20; C08G 2261/95; C08G 2261/3221; C08G 2261/3327; C08G 2261/1412; C08G 2261/1426; C08G 2261/1422; C08G 2261/148; C08G 2261/228; C08G 2261/124; G03F 7/0044

(57) ABSTRACT

A photoimageable composition for preparing a polymeric binder having of one or more of monomer unit copolymers, a photoactive compound, and one or more organometallic compounds is provided. The copolymers include one or more hydroxyl or carboxyl functional groups that react with the organometallic compound to form a crosslinked network upon curing. The photoimageable compositions may be particularly useful in forming a pixel-defining layer of an electronic device. such as an organic light emitting diode. In particular, photoimageable compositions in accordance with embodiments of the present invention are insoluble in the developer prior to exposure to radiation, soluble in the developer following radiation exposure, and have relatively high glass transition temperatures (T_{g}) making them useful in forming a pixel-defining layer.

### FIELD

The present invention relates to compositions for the surface treatments of an organic light emitting diode (OLED) panel, and in particular, to compositions for forming a photosensitive pixel-defining layer on an OLED panel.

### BACKGROUND

OLED displays are a promising technology due at least in part to their light weight, high contrast, high response rate, low power consumption, and brightness. Conventional methods for manufacturing OLED displays include the formation of a plurality of grid-like cells, referred to as a pixel-defining layer, in which a photo-luminescent organic compound is deposited to define a pixel.

The pixel-defining layer is typically prepared in a multi-step process which may utilize photolithography techniques. In a first step, a layer comprising a photosensitive polymer is deposited on a substrate, such as an electrode. The composite structure comprising the substrate and layer of photosensitive polymer are then pre-baked to remove any solvent. In a subsequent step, the layer comprising the photosensitive polymer is selectively exposed to masked radiation (e.g., using lithography techniques) in a desired pattern. The structure is then developed (immersed in a developer solvent solution) to remove select portions of the layer and thereby form a desired pattern in the layer of the photosensitive polymer. In a final step, the structure is subjected to a curing bake to form the pixel-defining layer.

Polyimide is a photo sensitive material that is commonly used in the preparation of pixel-defining layers. However, due to its high cost there has been a desire to find a low cost alternative. One such alternative is silsesquioxane (SSQ).

SSQ has gained more and more attention due to its good thermal stability and lithography performance when compared to the polyimide counterpart. Consequently, extensive research on silsesquioxanes as semiconductors, insulators and OLEDs has been done by many companies and universities. SSQ-based materials typically have low dielectric constants (k), which makes them good thin film insulators. SSQ materials also have some disadvantages including difficulties with respect to control of film thickness and silsesquioxanes' tendency to be unstable in solvents.

Accordingly, there still exists a need for improved materials for forming a pixel-defining layer of an OLED.

### SUMMARY

Embodiments of the present invention are directed to photoimageable compositions for preparing a polymeric binder comprised of one or more of copolymers, a photoactive compound (PAC), and one or more organometallic compounds. The copolymers include one or more hydroxyl or carboxyl functional groups that react with the organometallic compound to form a crosslinked network upon curing.

The inventors of the present invention have discovered that compositions in accordance with embodiments of the invention may be particularly useful in forming a pixel-defining layer. In particular, photoimageable compositions in accordance with embodiments of the present invention are insoluble in the developer prior to exposure to radiation, soluble in the developer following radiation exposure, and have relatively high glass transition temperatures (T_{g}) making them useful in forming a pixel-defining layer.

During the curing bake step, the patterned pixel-defining layer is exposed to relatively high temperatures in order to cure (e.g., crosslink) the polymer. In particular, the organometallic compounds react with the carboxyl and/or hydroxyl groups on the polymer to form a crosslinked polymer network or matrix. Advantageously, the relatively high glass transition temperatures (T_{g}) of the composition permits the composition to be exposed to curing temperatures with little to no lateral flow of the polymer binder.

In one embodiment, the invention provides a photoimageable composition for preparing a crosslinked film comprising a copolymer having at least a first monomer unit (1) and a second monomer unit (2) that is distinct from the first monomer unit (1), and wherein the first monomer unit (1) comprises one or more of a carboxyl or hydroxyl group; a photoactive compound; and an organometallic compound. In some embodiments, the photoimageable composition may also include a solvent.

In a preferred embodiment, the first monomer unit (1) comprises a norborene or acrylate residue. in some embodiments, the second monomer unit (2) is residue of a vinyl monomer having a phenyl, benzyl, or benzocyclobutene moiety, a residue of a substituted acrylate monomer having a benzyl moiety, a phenyl moiety, or an ether benzocyclobutene moiety, a residue of a styrene monomer, or a residue from a norborene monomer having a benzocyclobutene ester moiety.

In one embodiment, the first monomer unit is selected from the group consisting of

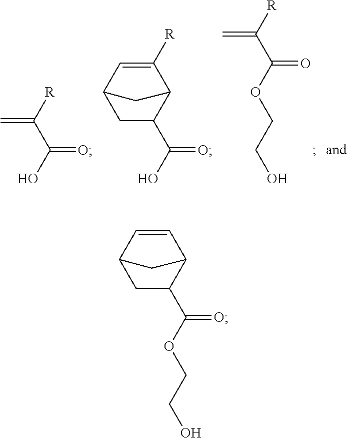

and the second monomer unit is selected from the group consisting of

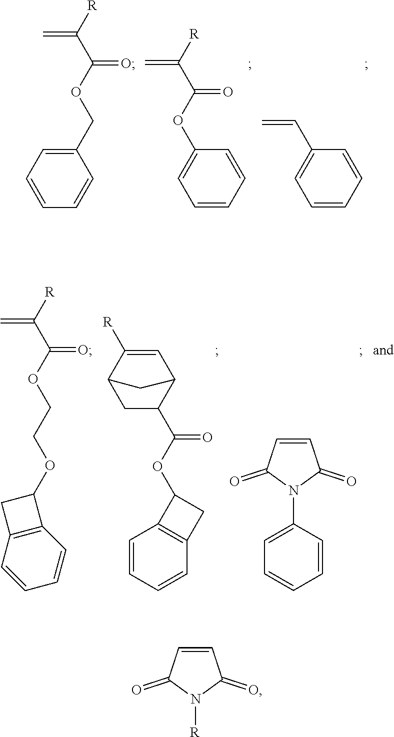

wherein R is a methyl group, hydrogen or deuterium. In one embodiment of the copolymer the amount of the first monomer unit in the copolymer is between 8 and 40 weight percent, based on the total weight of the copolymer, and the amount of the second monomer unit in the copolymer is between 60 and 92 weight percent based on the total weight of the copolymer.

In some embodiments, the first monomer unit (1) may comprise a residue of one or more of methacrylate and hydroxyethyl methacrylate, and the second monomer unit (2) may comprise a residue of one or more of benzyl methacrylate, styrene, a substituted norborene, and an n-substituted maleimide.

In further embodiments, the photoimageable composition may further comprise a third monomer unit (3) comprising a residue of a maleimide. In a preferred embodiment, the amount of the first monomer unit (1) in the copolymer is between 8 and 40 weight percent, based on the total weight of the copolymer, the amount of the second monomer unit (2) in the copolymer is between 60 and 92 weight percent, based on the total weight of the copolymer, and the amount of third monomer unit (3) in the copolymer is between 16 and 40 weight percent, based on the total weight of the copolymer,.

The organometallic compound may be selected from the group consisting of: compounds having the following formula (A):

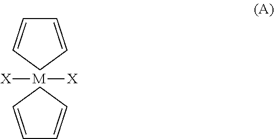

wherein M is a metal atom, and preferably M is a metal atom selected from the group consisting of Sc, Ti, V, Cr, Mn, Fe, Co, Ni, Cu, Zn, Zr, Nb, Mo, Tc, Ru, Rh, Pd, Ag, and Cd;

X is a halogen, preferably X is chlorine or bromine, or OR, wherein R is a Ci-C8 linear, branched, cyclic alkyl, or substituted alkyl group;

compounds having the following formulas (B) and (C):

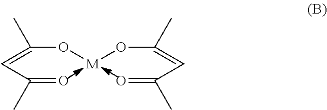

wherein M is a metal atom, preferably M is a metal atom selected from the group consisting of Sc, Ti, V, Cr, Mn, Fe, Co, Ni, Cu, Zn, Zr, Nb, Hf, Mo, Tc, Ru, Rh, Pd, Ag, and Cd, and more preferably M is a metal atom selected from the group consisting of Ti, V, Cr, Mn, Hf, Fe, Co, Ni, Cu, Zn, Zr, and Nb;

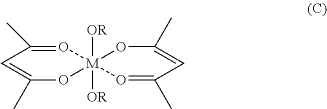

wherein M is a metal atom selected from the group consisting of Sc, Ti, V, Cr, Mn, Fe, Co, Ni, Cu, Zn, Zr, Nb, Hf, Mo, Tc, Ru, Rh, Pd, Ag, and Cd, and R is C₁-C₆ alkyl group; and

metallic alkoxy compounds having the following formula M(OC₁-C₄), wherein M is a metal atom selected from the group consisting of Sc, Ti, V, Cr, Mn, Fe, Co, Ni, Cu, Zn, Zr, Nb, Hf, Mo, Tc, Ru, Rh, Pd, Ag, and Cd.

The photoactive compound may be selected from the group consisting of

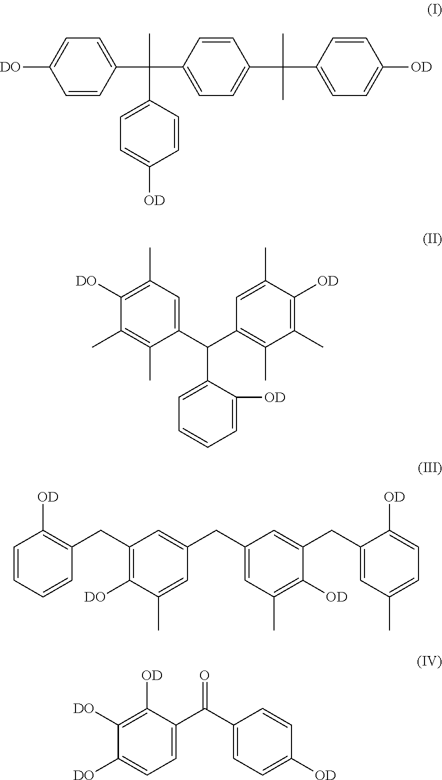

wherein D is a hydrogen atom, a deuterium atom, or a compound having the following formula:

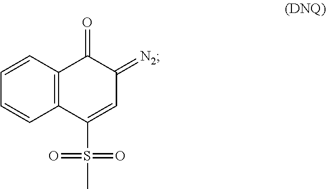

and

a polymeric material selected from the group consisting of

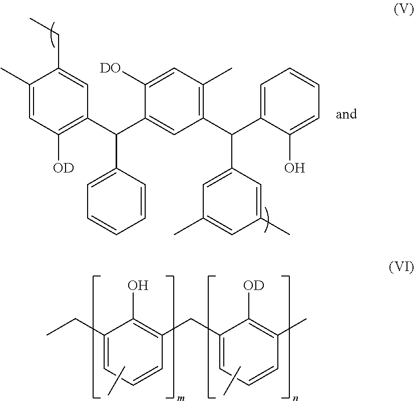

wherein D is the same as described above.

In a preferred embodiment, the amount of the photoactive compound is from 8 to 22 weight percent, based on the total weight of the composition, and the amount of organometallic compound is from 10 to 20 weight percent, based on the total weight of the composition.

In some embodiments, the photoimageable composition may comprise an additive selected from the group consisting of organomodified polymethylsiloxane, polyalkylene glycol based copolymers, and fluorosurfactants. As explained below, the additive may help remove any residual left in the patterned holes formed in a patterned film layer, such as a pixel-defining layer, prepared from the photoimageable composition.

In one embodiment, the copolymer is selected from the group consisting of

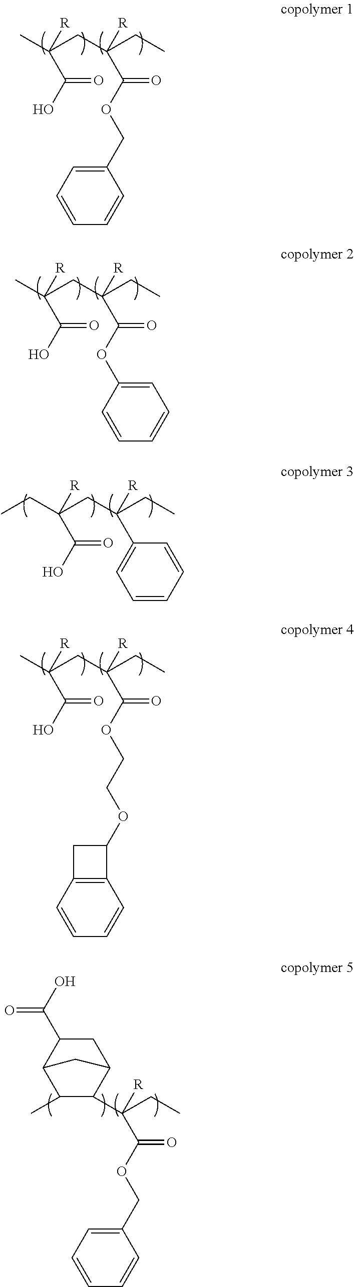

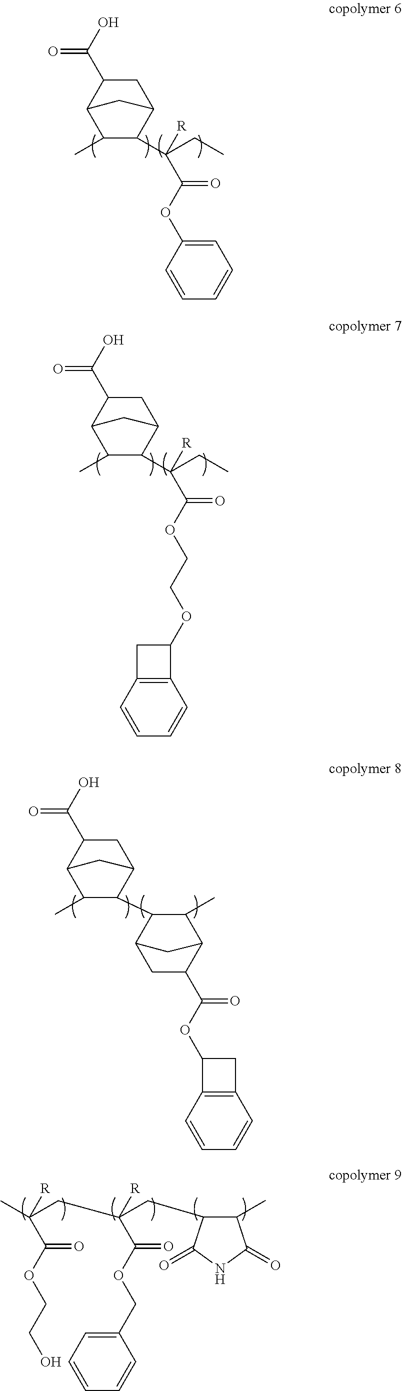

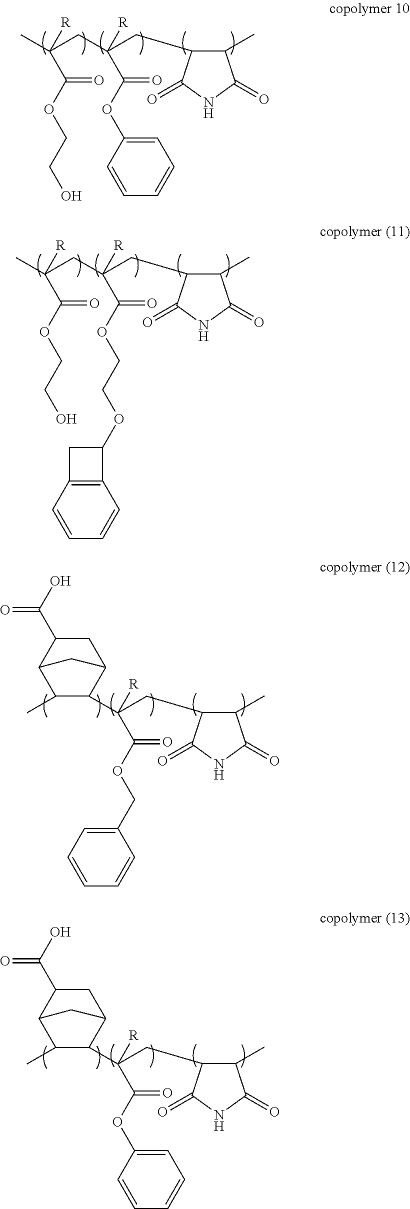

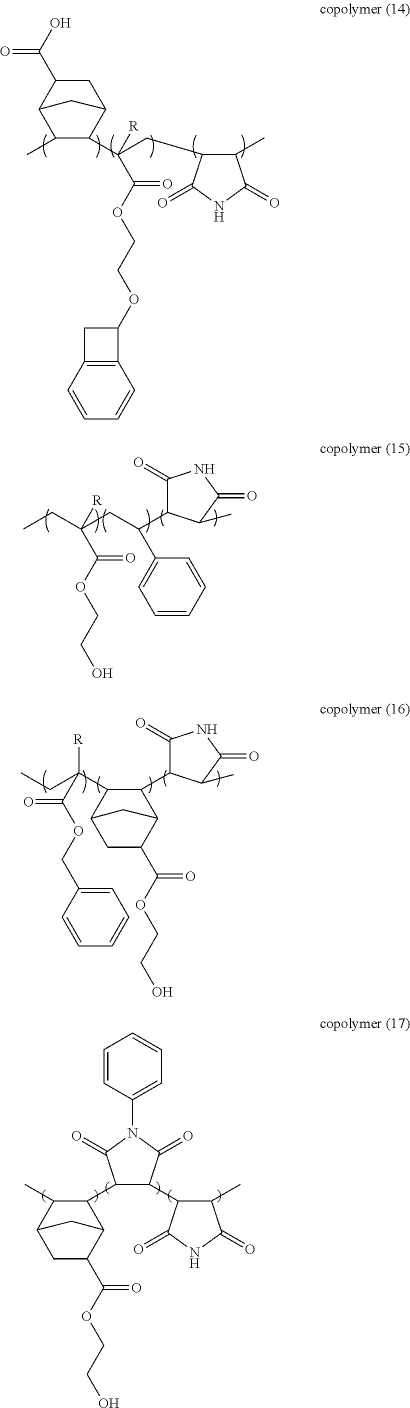

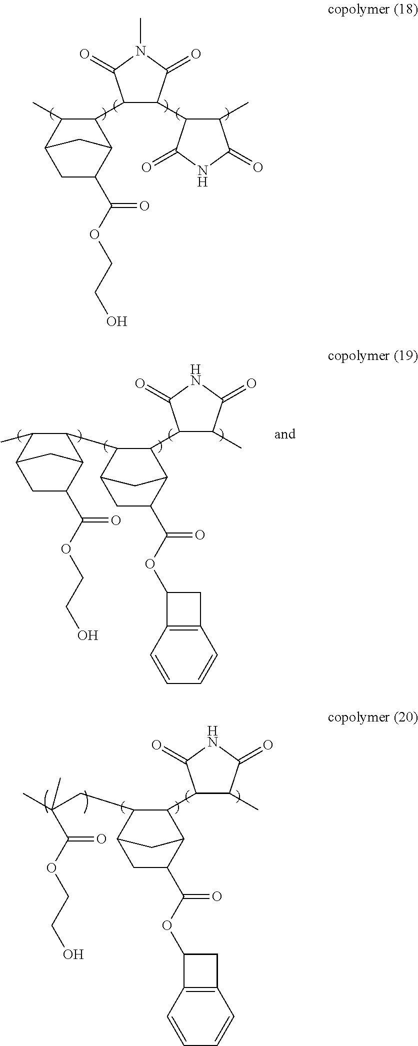

wherein R is hydrogen, deuterium, or a C₁-C₆ alkyl group, and wherein in copolymers having at least three monomer units, the first monomer unit is preferably between 8 and 40 weight percent, and more preferably between 10 and 35 weight percent, and even more preferably, between 15 and 32 weight percent; the second monomer unit is preferably between 60 and 92 weight percent, and more preferably between 65 and 90 weight percent, and even more preferably, between 68 and 88 weight percent; and the third monomer unit is preferably between 16 and 40 weight percent, and more preferably between 20 and 35 weight percent, and even more preferably, between 22 and 32 weight percent.

Photoimageable compositions in accordance with embodiments of the present invention may be used to prepare a polymer binder comprising a matrix of crosslinked chains of a random copolymer having a first monomer unit (1) comprising one or more of a carboxyl or hydroxyl groups and a second monomer unit (2) that is distinct from the first monomer unit, and wherein the carboxyl or hydroxyl groups of the first monomer unit (1) are crosslinked to each other via an organometallic compound to define a crosslinked polymeric network or matrix. In particular, embodiments of the present invention are particularly useful in preparing pixel-defining layers for use in the manufacture of organic light emitting diodes.

In one embodiment, the present invention is directed to a polymer binder prepared from the photoimageable composition comprising the first and second monomer units (1) and (2) as discussed above and below, and further comprising a third monomer unit (3) comprised of a residue of a maleimide monomer. In a preferred embodiment, the first monomer unit (1) of the polymer binder comprises a norborene or acrylate residue, and the second monomer unit (2) is residue of a vinyl monomer having a phenyl, benzyl, or benzocyclobutene moiety, a residue of a substituted acrylate monomer having a benzyl moiety, a phenyl moiety, or an ether benzocyclobutene moiety, a residue of a styrene monomer, or a residue from a norborene monomer having a benzocyclobutene ester moiety.

Embodiments of the present invention are also directed to an electronic device, such as an organic light emitting diode, comprising a film layer comprised of a polymeric binder prepared from a photoimageable composition in accordance with the present invention.

Embodiments of the present invention are also directed to a method of preparing a pixel-defining layer comprising the steps of
providing a substrate;
forming a plurality of electrodes on the substrate;
coating a layer of the inventive photoimageable composition on said
   substrate overlying the electrodes, wherein said photoimageable composition comprises a copolymer having at least a first monomer unit (1) and a second monomer unit (2) distinct from the first monomer unit (1), wherein the first monomer unit (1) comprises one or more of a carboxyl or hydroxyl group, a photoactive compound, an organometallic compound, and a solvent;
prebaking the substrate with the layer of said photoimageable composition to remove the solvent, preferably at a temperature below the crosslinking temperature of the photoimageable composition;
exposing the substrate to masked radiation;
developing said substrate in a developing solution to form a desired pattern on the layer of the photoimageable composition; and
baking the substrate with the patterned pixel-defining layer at a temperature sufficient to crosslink the carboxyl or hydroxyl groups of the first monomer unit (1) via said organometallic compound to form a pixel-defining layer.

Embodiments of the present invention may further comprise depositing one or more organic layers (e.g., hole injection and transport layer(s), emissive layer(s), and hole injection and transport layer(s)) within the patterned pixel, and a cathode material overlying the one or more of the organic layers to form an organic light emitting diode.

In one embodiment, the step of baking the substrate is performed at a temperature ranging from 150 to 260° C. In one embodiment, the step of exposing the substrate radiation comprises exposure to I-line radiation.

### BRIEF DESCRIPTION OF THE DRAWINGS

FIGS. 1(a), 1(b) and 1(c) are cross-section Scanning Electronic Microscopy (SEM) images of hole patterns.

FIGS. 2(a), 2(b), 2(c) and 2(d) are cross-section SEM images for a formulation based on Sample 22 (copolymer 1).

FIG. 3 is a cross-section SEM image for a formulation based on copolymer (16).

FIG. 4 is a cross-section SEM image for a developed polymer layer to which a polyalkylene glycol based copolymer is added.

FIG. 5 is a cross-section SEM image fora developed polymer layer to which a polymeric hybrid photoactive compound (PAC) is added.

### DETAILED DESCRIPTION

Photoimageable compositions in accordance with embodiments of the present invention comprise one or more copolymers, a photoactive compound (PAC), and one or more organometallic compounds.

The photoimageable composition, also referred to herein as a photoresist, includes a photosensitive polymer and includes a light-reactive material. Photoresist materials may be generally classified into two types, for example, a negative type and a positive type. Regarding the negative type photoresist material, a part that receives light is hardened and the other part is developed. Regarding the positive type photoresist material, a part that receives light is developed. The photoimageable compositions of the instant invention are directed to a positive type photoresist.

### Copolymers

The photoimageable compositions comprise copolymers having at least two different monomer units:

(1) The first monomer unit comprises a cross-linking unit that comprises one or more of a hydroxyl or carboxyl moiety. As discussed in greater detail below, the hydroxyl or carboxyl moieties of the cross-linking unit form crosslinks by bonding with organometallic compounds during a curing step to form a crosslinked polymeric network or matrix.

In some embodiments of the invention, the first monomer unit may also function as a developer solubility unit.

(2) The second monomer unit comprises a solubilizing unit that helps to control the solubility of the copolymer in a solvent. The solubilizing unit is preferably hydrophobic and may comprise alkyl chains having one or more moieties (e.g., rings, such as a phenyl moieties, styrenic moieties, ether moieties, carboxyl moieties, and ester moieties) that participate in one or more of crosslinking or solubilization of the copolymer.

Generally, the solubilizing unit may be selected to provide the copolymers with a desired solubility in the solvent, and to help control the developability of the copolymer in a developer solution.

Preferred copolymers may comprise additional monomer unit in addition to the first and second monomer units (1) and (2), i.e., the copolymers may contain three, four or more monomer units. For at least certain applications, a copolymer (total of 2 different monomer units) will be suitable. Thus, references herein to copolymers are inclusive of polymers that comprise 2, 3, 4 or more distinct monomer units. As should be understood, the term polymer or copolymer as referred to herein indicates a polymer that comprises one or more sections of a first chemical structure separated by one or more sections of a different chemical structure or composition.

In one embodiment, the amount of the first monomer unit (1) in the copolymer is between 8 and 40 weight percent, and more preferably between 10 and 35 weight percent, and even more preferably, between 15 and 32 weight percent. Preferably, the amount of the second monomer unit (2) in the copolymer is between 60 and 92 weight percent, and more preferably between 65 and 90 weight percent, and even more preferably, between 68 and 88 weight percent.

In one embodiment, the first monomer unit (1) may include a variety of moieties including, for example —OH groups, —COOH groups, —COOH(CH₂)₁₋₆OH groups, and substituted norborenes, such as norborenes substituted with carboxylic groups and hydroxyethyl ester carboxylates.

Examples of preferred monomers for the first monomer unit (1) may include C₁₋₆ acrylates, such as methyl acrylate, ethyl acrylate, and hydroxyethyl methacrylate; substituted norborenes such as 2-carboxylbicyclo[2,2,1]heptane and bicyclo[2.2.1]hept-5-ene-2-carboxylic acid 2-hydroxyethyl ester (also known as 2-hydroxyethyl 5-norbornene-2-carboxylate).

Preferred monomers for the first monomer unit (1) may be selected from the group consisting of

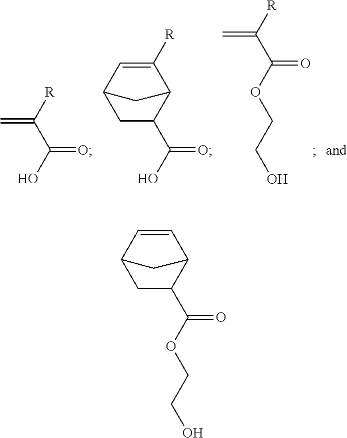

wherein R is hydrogen, deuterium, or a substituted or unsubstituted alkyl preferably having 1 to 6 carbon atoms, and more typically, from 1 to 2 carbon atoms. Preferably, R is hydrogen or a methyl group.

In one embodiment, the solubilizing second monomer unit (2) may include a variety of moieties including, for example, —CH₃ groups, —C(═O)OH groups, —O— groups, phenyl groups, benzyl group, styrenic groups, bicyclic groups, such as norborenes and benzocyclobutene, n-substituted maleimides, and combinations thereof.

Preferred monomers for the second monomer unit (2) may be selected from the group consisting of

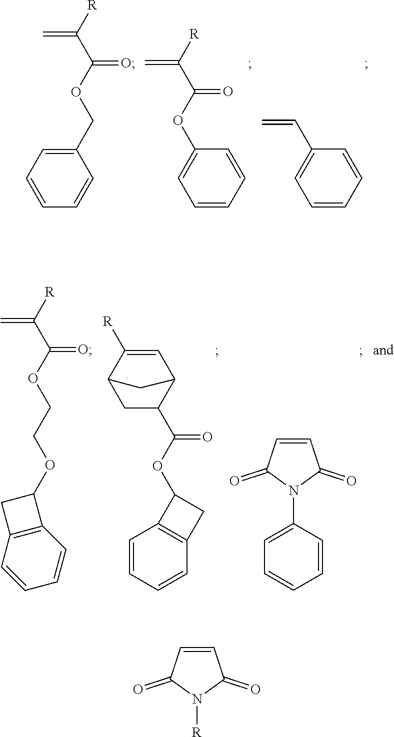

wherein R is hydrogen, deuterium, or a substituted or unsubstituted alkyl, preferably having 1 to 6 carbon atoms, and more typically, from 1 to 2 carbon atoms.

In a preferred embodiment, the second monomer unit (2) comprises a residue of a vinyl monomer having a phenyl, benzyl, or benzocyclobutene moiety. In one embodiment, the second monomer unit (2) comprises is a residue of a substituted acrylate monomer having a benzyl moiety, a phenyl moiety, or an ether benzocyclobutene moiety. In other embodiments, the second monomer unit (2) may comprise a residue of a styrene monomer. In still other embodiments, the second monomer unit (2) may be residue from a norborene monomer having a benzocyclobutene ester moiety.

Examples of preferred monomers for the second monomer unit (2) may include C₁-C₆ acrylates, such as methyl acrylate, ethyl acrylate; alkyl C₁-C₆ benzyl acrylates, such as benzyl methacrylates, styrenes, norborenes having esters of benzocyclobutene, n-substituted maleimides, such as n-methyl maleimide and n-phenyl maleimide.

In one embodiment, the second monomer unit (2) is free of any one of a hydroxyl or carboxyl moiety.

Specifically preferred copolymers for use in forming a pixel-defining layer include the following:

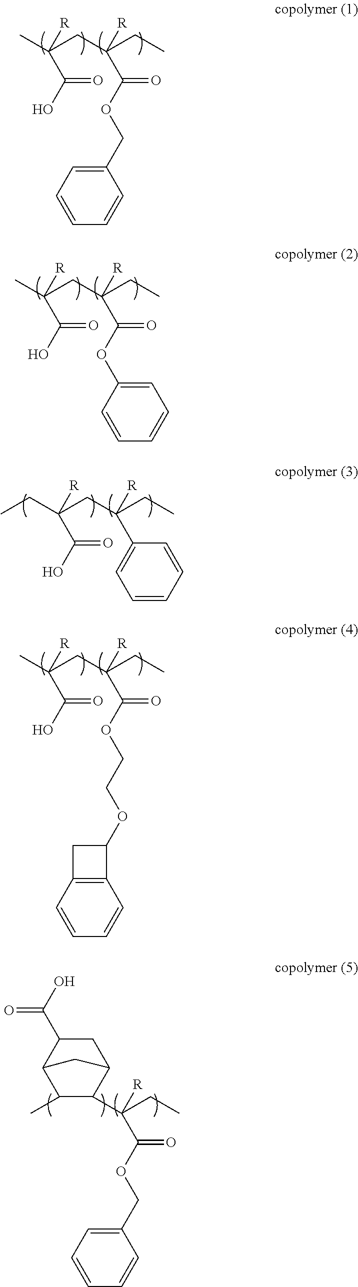

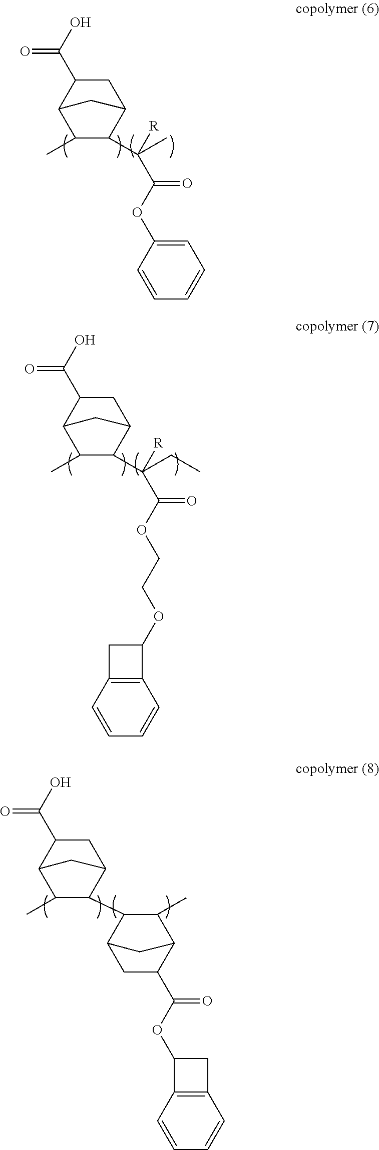

Preferably, the first monomer unit (1) is between 8 and 40 weight percent, and more preferably between 10 and 35 weight percent, and even more preferably, between 15 and 32 weight percent. Preferably, the second monomer unit (2) is between 60 and 92 weight percent, and more preferably between 65 and 90 weight percent, and even more preferably, between 68 and 88 weight percent.

In further embodiments, the random copolymers for use in the photoimageable composition may include copolymers having 3 of more monomer units. In this embodiment, the photoimageable composition may include first and second monomer units (1) and (2) as described above, and may include a third monomer unit (3):

(3) a thermal stability monomer unit comprising a residue of a maleimide monomer. It has been found that binder polymers comprising a thermal stability monomer unit generally have higher glass transition temperatures, and hence, higher thermal stabilities. For example, binder polymers comprising this third monomer unit have been prepared having glass transition temperatures of 160° C. or higher. Accordingly, in some embodiments the invention may provide a binder polymer having a higher thermal stability by incorporation of the third monomer unit (3). Such binder polymers may be particularly useful in applications requiring higher cure temperatures or higher glass transitions temperatures.

In a preferred embodiment, the third monomer unit (3) has the following formula:

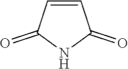

In copolymers having at least three monomer units, the amount of the first monomer unit (1) in the copolymer is preferably between 8 and 40 weight percent, and more preferably between 10 and 35 weight percent, and even more preferably, between 15 and 32 weight percent; the amount of the second monomer unit (2) in the copolymer is preferably between 60 and 92 weight percent, and more preferably between 65 and 90 weight percent, and even more preferably, between 68 and 88 weight percent; and the amount of the third monomer unit (3) in the copolymer is preferably between 16 and 40 weight percent, and more preferably between 20 and 35 weight percent, and even more preferably, between 22 and 32 weight percent.

Preferred copolymers having at least three monomer units include the following:

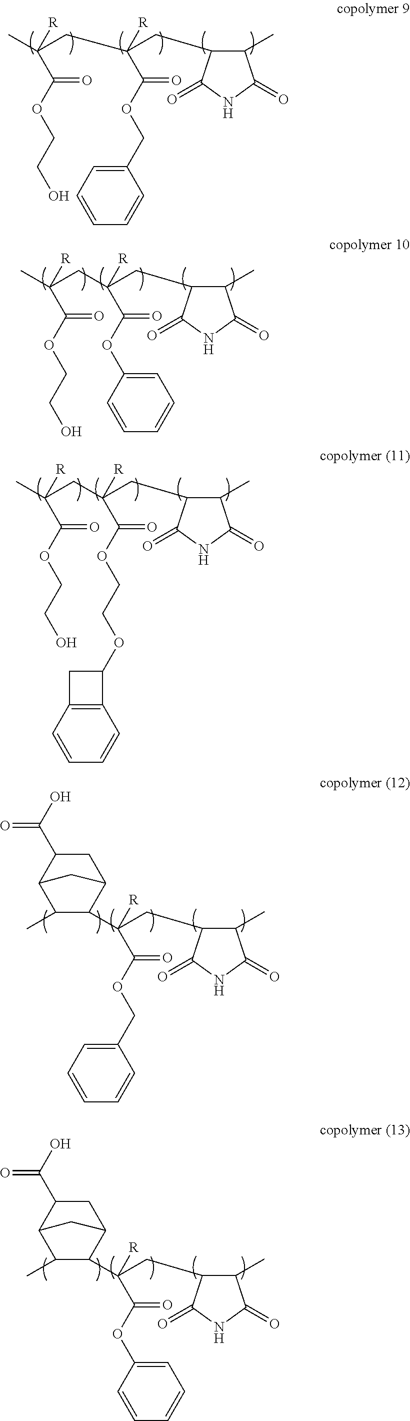

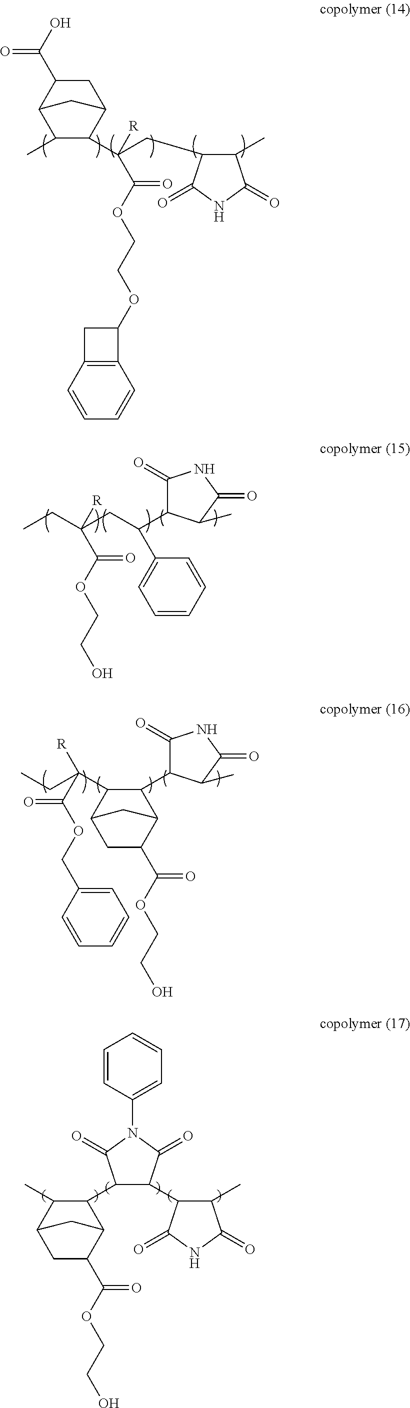

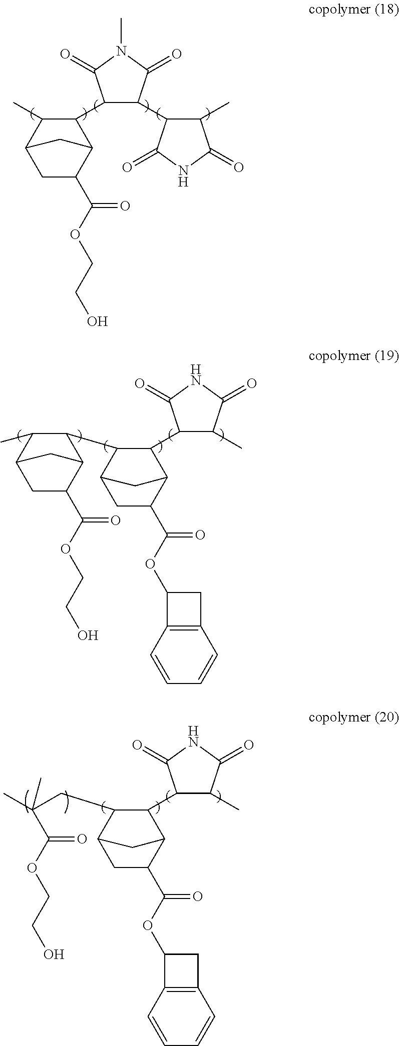

wherein R is hydrogen, deuterium, or a C₁-C₆ alkyl group. Preferably, R is a methyl group.

In copolymers having at least three monomer units, the first monomer unit (1) is preferably between 8 and 40 weight percent, and more preferably between 10 and 35, and even more preferably, between 15 and 32 weight percent; the second monomer unit (2) is preferably between 60 and 92 weight percent, and more preferably between 65 and 90 weight percent, and even more preferably, between 68 and 88 weight percent; and the third monomer unit (3) is preferably between 16 and 40 weight percent, and more preferably between 20 and 35 weight percent, and even more preferably between 22 and 32 weight percent.

The polymer binder comprising the copolymers is typically present in the photoimageable composition in an amount ranging from 45 to 85 weight percent, based on the total weight of the composition, exclusive of solvent. For example, the amount of the polymer binder may be from 50 to 80 weight percent, preferably from 60 to 80 weight percent, and even more preferably from 62 to 75 weight percent, based on the total weight of the composition, exclusive of solvent.

The copolymers in accordance with embodiments of the present invention may be prepared by free radical polymerization, e.g., by reaction of a plurality of monomers to provide the various copolymers discussed above in the presence of a polymerization initiator. In some embodiments, the polymerization may be performed at elevated temperatures, such as above 60° C. or greater. It should be recognized that reaction temperatures may vary depending on the reactivity of the particular monomers employed, and the boiling temperature of the solvent. As discussed above and exemplified in the Examples below, copolymers of the present invention may be highly useful as a polymer binder in compositions for forming a pixel-defining layer.

Generally, the polymerization reaction is carried out in a solvent. Suitable solvents may include propylene glycol methyl ether acetate (PGMEA), gamma butyrolactone (GBL), lactates, such as ethyl lactate, ethyl acetate, alcohols, such as propanols and butanols, and aromatic solvents such as benzene and toluene.

Preferably, polymers for use in the photoimageable composition of the invention also will be soluble in developer compositions (e.g., 0.26 N aqueous alkaline solutions such as 0.26 N tetramethyl ammonium hydroxide (TMAH) aqueous developer).

### Organometallic Compounds

Photoimageable compositions in accordance with embodiments of the invention also include one or more organometallic compounds.

Examples of suitable organometallic compounds include, for example, chelated metal compounds, compounds comprising a center metal (M) atom bound between two cyclopentadienyl anions, and metal alkoxy compounds.

Examples of compounds comprising a center metal (M) atom bound between two cyclopentadienyl anions include metallocenes and derivatives thereof. Typically, the metal atom is in the oxidation state II-IV.

In a preferred embodiment, the organometallic compounds have the following formula (A):

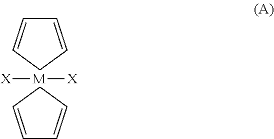

M is a metal atom, and may include, for example, Sc, Ti, V, Cr, Mn, Fe, Co, Ni, Cu, Zn, Zr, Nb, Mo, Tc, Ru, Rh, Pd, Ag, and Cd;

X is a halogen, such as chlorine and bromine, or OR, wherein R is a Ci-C8 linear, branched, cyclic alkyl, or substituted alkyl group.

Preferably, the metal atom is selected from the group consisting of Ti, V, Cr, Mn, Fe, Co, Ni, Cu, Zn, Zr, and Nb.

Examples of organometallic compounds include titanocene dichloride (dichloridobis(η⁵-cyclopentadienyl)titanium); zirconocene dichloride (bis(cyclopentadienyl)zirconium dichloride (IV)); niobocene dichloride (dichloridobis (η⁵-cyclopentadienyl)niobium); and vanadocene dichloride (dichloro bis(η⁵-cyclopentadienyl)vanadium(IV)).

Examples of chelated metal compounds include compounds having the following formulas (B) and (C):

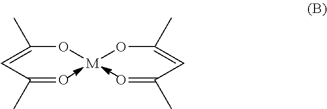

Wherein M is a metal atom, and may include, for example, Sc, Ti, V, Cr, Mn, Fe, Co, Ni, Cu, Zn, Zr, Nb, Hf, Mo, Tc, Ru, Rh, Pd, Ag, and Cd.

Preferably, the metal atom is selected from the group consisting of Ti, V, Cr, Mn, Hf, Fe, Co, Ni, Cu, Zn, Zr, and Nb.

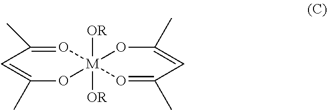

Wherein M is a metal atom, and may include, for example, Sc, Ti, V, Cr, Mn, Fe, Co, Ni, Cu, Zn, Zr, Nb, Hf, Mo, Tc, Ru, Rh, Pd, Ag, and Cd; and R is C₁-C₆ alkyl group. In a preferred embodiment, OR is a butoxy group.

Preferably, the metal atom is selected from the group consisting of Ti, V, Cr, Mn, Hf, Fe, Co, Ni, Cu, Zn, Zr, and Nb, and R is C1-C4 alkyl group. Preferably M is Zr.

Suitable metallic alkoxy compounds also include compounds having the following formula M(OC₁-C₄), wherein M is a metal atom, and may include, for example, Sc, Ti, V, Cr, Mn, Fe, Co, Ni, Cu, Zn, Zr, Nb, Hf, Mo, Tc, Ru, Rh, Pd, Ag, and Cd. Preferred metallic alkoxy compounds include zirconium n-butoxide, titanium n-butoxide, and hafnium n-butoxide.

The organometallic compounds are typically present in the photoimageable composition in an amount ranging from 8 to 25 weight percent, based on the total weight of the composition. For example, the amount of the organometallic compounds may be from 10 to 20 weight percent, preferably from 12 to 20 weight percent, and even more preferably from 12 to 18 weight percent, based on the total weight of the composition.

### Photoactive Compound

The photoactive compound generally comprises a compound that when mixed with copolymers, renders the photoimageable composition insoluble to the developer prior to being exposed to radiation (e.g., visible, ultraviolet, or X-ray photons or in the form of energetic electron beams).

A wide variety of different photoactive compounds may be used in the practice of the invention depending on the composition of the polymer binder. In a preferred embodiment, the photoactive compound is photosensitive to I-line radiation (365 nm) Examples of suitable I-line photoactive compounds may include compounds having at least 1, preferably 2 to 8 diazonaphtoquinone (DNQ) groups. Examples of photoactive compounds for use in embodiments of the invention are represented by formulas (I)-(VI) below,

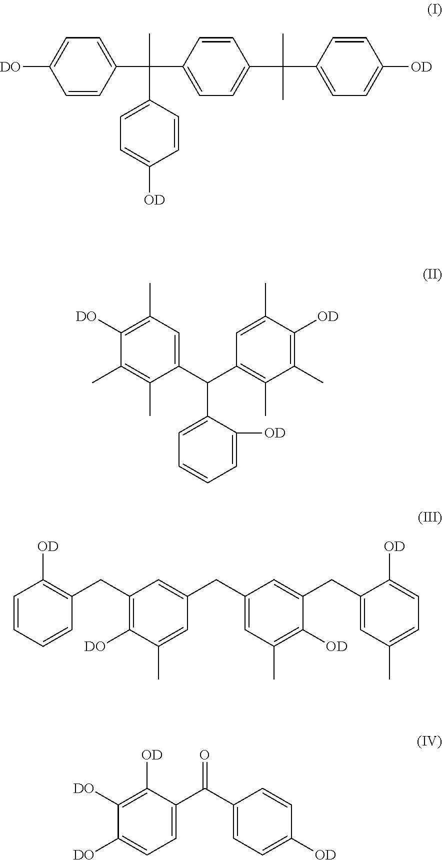

wherein D is a hydrogen atom, a deuterium atom, or a compound having the following formula:

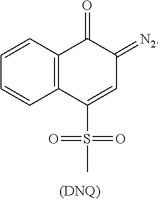

In addition to the aforementioned photoactive compounds, the photoactive compound may also comprise a polymeric material, such as a polymeric hybrid of the compound of formula (II) having the following formula:

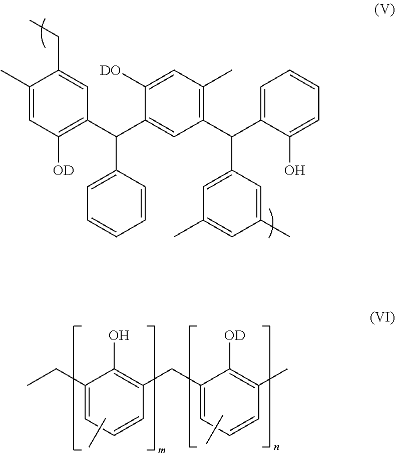

wherein D is a hydrogen atom, a deuterium atom, or DNQ. Preferably, the molecular weight of the polymeric PAC is between 6K and 15K Daltons.

Additional photoactive compounds include esters of 2-Diazo-1-naphthol-5-sulphochloride ester having a polyhydroxy phenol available from Miwon Commercial Co.

Generally, the amount of the photoactive compound in the photoimageable composition may be varied depending on the chemical nature of the monomers and the relative proportions of each monomer in order to provide the desired developer solubility prior to crosslinking. For example, in compositions having a greater proportion of one or more of the second and third units, it may be desirable to include a greater amount of the photoactive compound in the composition.

The photoactive compound is typically present in the photoimageable composition in an amount ranging from 5 to 25 weight percent, based on the total weight of the composition (solid content). For example, the amount of the photoactive compound may be from 8 to 22 weight percent, preferably from 10 to 20 weight percent, and even more preferably from 12 to 18 weight percent, based on the total weight of the composition.

In addition, to the above components the photoimageable composition may also include one or more residue removing additives. In some cases, it has been observed that a residue material, referred to as “scum” may be left on the pixel-defining layer following development. The inventors have discovered that the inclusion of an additive may help reduce or eliminate the presence of this so-called scum. Examples of additives that may be used include ograno siloxane copolymers, such as an organomodified polymethylsiloxane copolymers available from MOMENTIVE™ under the product name Silwet L-7604, polyalkylene glycol based copolymers, such as those available from The Dow Chemical Company under the tradename UCON™, and flurosurfactants, such as those available from OMNOVA Solutions under the product name POLYFOX™ 656.

When present, the amount of additive may range from 0.001 to 5 weight percent, based on the total weight of the photoimageable composition, and preferably from about 0.05 to 2 weight percent, and more preferably from about 0.1 to 1 weight percent.

In addition to the use of an additive, it has also been discovered that the use of a polymeric photoactive compound, such as the one described in formula (V) above, may also help reduce or eliminate scum.

Photoimageable compositions in accordance with embodiments of the invention also may contain other optional materials. For example, other optional additives include anti-striation agents, plasticizers, speed enhancers, etc. Such optional additives typically will be present in minor concentrations in the composition except for fillers and dyes which may be present in relatively large concentrations, e.g., in amounts of from about 5 to 30 percent by weight of the total weight of the composition's dry components.

As discussed previously, the inventive photoimageable compositions are thermally stable and exhibit desirable glass transition temperatures. As a result, the photoimageable compositions have little, if any, flow during the cure baking process. Consequently, the photoimageable compositions are good candidates for pixel-defining layers.

In one embodiment, photoimageable compositions in accordance with the invention may have glass transition temperatures ranging from about 90 to 300° C., and preferably, from about 99 to 275° C., and mor preferably, from about 150 to 270° C.

The photoimageable compositions described herein can be solution-processed into films having a thickness in the range of about 1 μm to about 50 μm, where the films subsequently can be crosslinked via thermal curing, into mechanically robust and ambient-stable materials suitable for use as a permanent layer in various electronic, optical, and optoelectronics devices. For example, the present materials can provide a photoimageable film having a thickness ranging from about 1.5 μm to about 25 μm, from about 1.5 μm to about 20 μm, from about 1.5 μm to about 15 μm, from about 1.5 μm to about 10 μm, and from about 17 μm to about 8 μm. In a preferred embodiment, the photoimageable composition may be used to prepare a film layer having a thickness from about 1.5 μm to about 3 μm.

A further aspect of the invention is directed to a method of forming a pixel-defining layer for use in an electronic device, such as an OLED.

In one embodiment of the present invention, the method for forming a pixel-defining layer on an OLED panel, comprises the following steps:

(A) providing a substrate;

(B) forming a plurality of electrodes on said substrate;

(C) coating a layer of the inventive photoimageable composition on said substrate with said electrodes;

(D) prebaking said substrate with said layer of said photoimageable composition;

(E) exposing said substrate to masked radiation;

(F) developing said substrate (e.g., immersion in a developer solution) to form a desired pattern on the layer of said photoimageable composition; and

(G) baking said substrate with patterned pixel-defining layer for crosslinking or curing said photoimageable composition to form said pixel-defining layer.

A pixel-defining layer (PDL) comprising the photoimageable composition may generally prepared following known procedures. For example, a PDL of the invention can be prepared as a coating composition by dissolving the components of the photoimageable composition in a suitable solvent such as, e.g., a glycol ether such as 2-methoxyethyl ether (diglyme), ethylene glycol monomethyl ether, propylene glycol monomethyl ether; propylene glycol monomethyl ether acetate; lactates such as ethyl lactate or methyl lactate, with ethyl lactate being preferred; propionates, particularly methyl propionate, ethyl propionate and ethyl ethoxy propionate; lactones, such as gamma butyrolactone;

a Cellosolve ester such as methyl Cellosolve acetate; an aromatic hydrocarbon such toluene or xylene; or a ketone such as methylethyl ketone, cyclohexanone and 2-heptanone. Typically the solids content of the photoimageable composition varies between 5 and 35 percent by weight of the total weight of the photoresist composition. Blends of such solvents also are suitable.

Liquid photoimageable compositions may be applied to a substrate such as by spinning, dipping, roller coating or other conventional coating technique. When spin coating, the solids content of the coating solution can be adjusted to provide a desired film thickness based upon the specific spinning equipment utilized, the viscosity of the solution, the speed of the spinner and the amount of time allowed for spinning. Preferably, the photoimageable composition is coated through spin-coating of 1000 to 3000 rpm on the substrate.

Photoimageable composition compositions used in accordance with the invention may be suitably applied to substrates conventionally used in processes involving coating with photoresists. For example, the photoimageable composition may be applied over silicon wafers or silicon wafers coated with silicon dioxide for the production of microprocessors and other integrated circuit components. are also suitably employed. The photoimageable composition also may be suitably applied over an antireflective layer, particularly an organic antireflective layer.

In a preferred embodiment, the substrate comprises a substrate used in OLED devices. For example, the substrate may be transparent or not transparent. Examples of materials for use as the substrate may include aluminum oxide, gallium arsenide, ceramic, quartz, copper, glass substrates, plastic substrates, and the like. Preferably, the substrates used in the present invention are sodalime glasses, boron silica glasses, plastics or silicon wafers.

In a preferred embodiment, the substrate includes one or more electrodes, such as an anode, onto which the photoimageable composition may be coated. The anode suitable for the present invention can be any conventional material for electrical conductance. Preferred anode materials include conductive metal oxides, such as indium tin oxide (ITO) and indium zinc oxide (IZO), aluminum zinc oxide (AlZnO), SnO₂, In₂O₃ doped with ZnO, CdSnO or antimony and metals.

Following coating of the photoimageable composition onto a surface, the composition may be dried by heating to remove the solvent until preferably the photoimageable composition is tack free. This drying step is often referred to as a “soft bake” or “prebaking” because it is performed at a temperature that is high enough to evaporate the solvent, but not high enough to result in curing of the photoimageable composition. Typically, during prebaking the layer of the photoimageable composition is heated to a temperature ranging from 60 to 130° C., and in particular, from about 70 to 85° C.

The photoimageable composition layer is then exposed to masked radiation with the exposure energy typically ranging from about 1 to 100 mJ/cm², dependent upon the exposure tool and the components of the photoimageable composition. During exposure, the exposed portions of the photoimageable composition layer are rendered soluble in a developer solution so that such portions may be selectively removed.

Preferred exposure wavelengths for embodiments of the invention may include sub-400 nm wavelengths e.g., 365 nm, and sub-200 nm wavelengths, e.g., 193 nm. In particular, the photoimageable compositions are preferably photoactivated by a short exposure wavelength, particularly a sub-400 nm, sub-300 and sub-200 nm exposure wavelength, with I-line (365 nm) being particularly preferred exposure wavelengths.

The radiation can be masked to expose the photoimageable composition to a variety of different patterns. In particular, the pattern of the pixel-defining layer is not limited to any particular pattern. In one embodiment, the pixel-defining layer may comprise a first plurality of parallel stripes that perpendicularly intersect with a second plurality of parallel stripes to define selective open portion areas (e.g., a pattern of multiple pixel windows) on the electrodes (anodes) on the substrate.

Following exposure to radiation, the layer is then developed by treatment with a solvent to selectively remove portions of the layer that have been exposed to the radiation, and thereby define the pixel-defining layer having a desired pattern. The development of the pixel-defining layer can be achieved by any conventional method and chemical.

The pixel-defining layer may be developed with a developer solution of 2.38% of tetramethyl ammonium hydroxide (TMAH) or 2.38% tetrabutyl ammonium hydroxide (TBAH). Other developer solutions may also be used.

The developed and patterned pixel-defining layer can then be subjected to a curing bake to cure or crosslink the random copolymers of the photoimageable composition. Depending on the glass transition temperature of the copolymer, the curing bake temperature may range from about 100 to 260° C. In embodiments in which the copolymer has a higher glass transition temperature, the curing bake temperatures may range from 160 to 260° C., and in particular, from about 180 to 260° C. In a preferred embodiment, the curing bake temperature is at least higher than 200° C. Most preferably, the baking temperature is at a temperature higher than 250° C.

In a preferred embodiment, development of the pixel-defining layer results in the formation of a plurality of ramparts which protrude outwardly on the substrate and generally includes a first plurality of parallel lines that intersect with a second plurality of parallel lines to define open window areas which are configured to receive organic electroluminescent materials therein. The open window areas of the pixel-defining layer are the locations of future pixels after deposition of subsequent organic electroluminescent materials and second electrodes, such as cathodes.

After the pixel-defining layer is formed, the process for forming an organic electroluminescent device, such as an OLED, may be achieved subsequently.

For example, in one embodiment an organic electroluminescent device may be formed after a plurality of first electrodes (anodes) and ramparts defined by the pixel-defining layer are formed. Organic electroluminescent materials are then deposited on the substrate and selectively on anodes. The organic electroluminescent materials may be deposited as a single layer or optionally multiple layers (e.g., hole injection layers, hole transporting layers, emitting layers, electron injection layers, electron transporting layers, etc.) on the substrate and selectively on anodes.

A plurality of cathodes (second electrodes) then form on the organic electroluminescent materials on the substrate. The formation of cathodes (second electrodes) can be achieved through conventional deposition methods. The organic electroluminescent materials are sandwiched by cathodes (second electrodes) and the anodes (first electrodes) on the substrate. The open portions where anodes (first electrodes) and cathodes (second electrodes) locate between ramparts are the light emitting portions (i.e., pixels) of the OLED device.

The second electrode (cathode) suitable for the present invention can be any conventional material for electrical conductance. For example, the cathode may comprise any suitable material or combination of materials that are capable of conducting electrons and injecting them into the organic electroluminescent material layers. The cathode may be transparent, opaque, or reflective. In one embodiment, the cathode may comprise a single layer or may comprise multiple layers.

Generally, the cathode comprises a thin film of low work function metal or metallic alloy, such as below 4 eV. Examples of suitable materials for the cathode include Al, Ag, In, Mg, Ca, Li, Cs, and combinations thereof.

Embodiments of the present invention may be used to prepare OLED panels and devices. The color of the pixels of the OLED panels through the methods of the present invention can be any conventional colors such as red, green or blue. The color of the pixels of the OLED panels can be controlled by the organic electroluminescent material. The OLED panels of the present invention can be either panels with single color, multiple colors or full colors.

The OLED devices achieved through the method of the present invention can be applied to any display of images, graphs, symbols, letters and characters for any apparatus. Preferably, the OLED devices of the present invention are applied to the display of televisions, computers, printers, screens, vehicles, signal machines, communication devices, telephones, lights, electric books, microdisplays, personal digital assistants (PDA), game machines, game goggles and airplanes.

More detailed examples are used to illustrate the present invention, and these examples are used to explain the present invention. The examples below, which are given simply by way of illustration, must not be taken to limit the scope of the invention.

### EXAMPLES

In the following examples, various copolymers in accordance with the invention were generally prepared in accordance with the following procedures in which the following synthesis procedures are used as representative examples. Synthesis of copolymer (1)

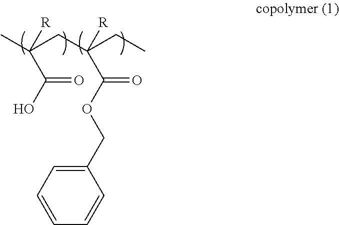

30 grams of propylene glycol methyl ether acetate (as solvent) was added into a 3 necked round bottom flask and heated under magnetic stirring to a temperature of 99° C. 30 grams of methacrylate acid (MAA) (the first monomer unit (1)) and benzyl methacrylate (BMA) (the second monomer unit (2)) at a weight ratio of 20/80, respectively, were dissolved in a flask containing 30 gram of solvent. Subsequently, 0.9 grams dimethyl-2, 2′-azobis(2-methyl propionate) (V-601 made by Wako Pure Chemical Industries) was added in the flask as polymerization initiator. The monomer mixture was drop fed into the heated solvent at 99° C. drop by drop under magnetic stirring. The feeding rate was 9.62 μl/s. After about 1.5 hours, the drop feeding of the monomer solution was completed. Stirring at 99° C. was maintained for another 2 hours to complete the reaction.

### Synthesis of Copolymer (3)

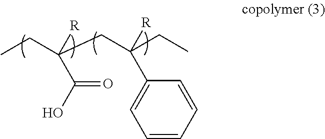

30 grams of propylene glycol methyl ether acetate (PGMEA) (as solvent) were added into a 3 necked round bottom flask and heated under magnetic stirring to a temperature of 99° C. 30 grams of methacrylate acid (MAA) (the first monomer unit (1)) and styrene (ST) (the second monomer unit (2)) at a weight ratio of 20/80, respectively, were dissolved in a flask containing 30 gram of PGMEA solvent. Subsequently, 0.9 grams dimethyl-2, 2′-azobis(2-methyl propionate) (V-601 made by Wako Pure Chemical Industries) was added in the flask as polymerization initiator. The monomer mixture was drop fed into the heated solvent at 99° C. drop by drop under magnetic stirring. The feeding rate was 9.62 μl/s. After about 1.5 hours, the drop feeding of the monomer solution was completed. Stirring at 99° C. was maintained for another 2 hours to complete the reaction.

### Synthesis of Copolymer (9)

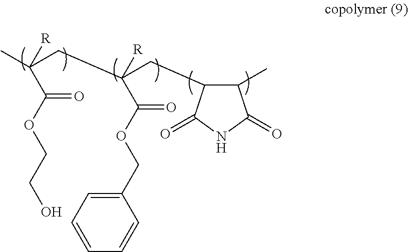

30 grams of propylene glycol methyl ether acetate (PGMEA) (as solvent) were added into a 3 necked round bottom flask and heated under magnetic stirring to a temperature of 99° C. 30 grams total of monomers hydroxyethyl methacrylate (HEMA) (the first monomer unit (1)), benzyl methacrylate (BMA) (the second monomer unit (2)), and maleimide (Ml) (monomer unit (3)) at a weight ratio of 35/45/20, respectively, were dissolved in a flask containing 30 gram of PGMEA solvent. Subsequently, 0.9 grams dimethyl-2, 2′-azobis(2-methyl propionate) (V-601 made by Wako Pure Chemical Industries) was added in the flask as polymerization initiator. The monomer mixture was drop fed into the heated solvent at 99° C. drop by drop under magnetic stirring. The feeding rate was 9.62 μl/s. After about 1.5 hours, the drop feeding of the monomer solution was completed. Stirring at 99° C. was maintained for another 2 hours to complete the reaction.

### Alternative Synthesis for Copolymer (9)

30 grams of ethyl lactate (as solvent) and a magnetic bar were added into a 3 necked round bottom flask and heated to a temperature of 70° C. 30 grams total of monomers hydroxyethyl methacrylate (HEMA), benzyl methacrylate (BMA), and maleimide (Ml) were added at a weight ratio of /25/49/26, respectively, were dissolved in a flask containing 30 g of ethyl lactate. Subsequently, 2.1 grams of dimethyl-2, 2′-azobis(2-methyl propionate) (V-601 made by Wako Pure Chemical Industries) along with approximately 2 ml of ethyl lactate was added in the flask as polymerization initiator. The monomer mixture was drop fed into the heated solvent at 70° C. drop by drop under magnetic stirring. The feeding rate was 9.62μl/s. After about 1.5 hours, the drop feeding of the monomer solution was completed. Stirring at 70° C. was maintained for another 2 hours to complete the reaction.

### Synthesis of Copolymer (16)

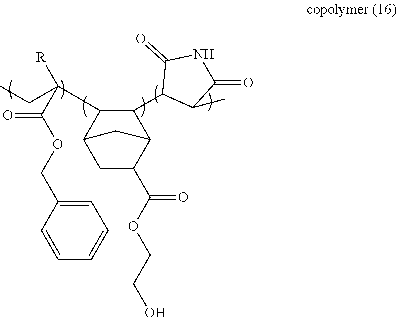

30 grams of ethyl lactate (as solvent) and a magnetic bar were added into a 3 necked round bottom flask and heated to a temperature of 70° C. 30 grams total of monomers benzyl methacrylate (BMA) (the second monomer unit (2)), 2-hydroxyethyl bicyclo[2.2.1]hept-5-ene-2-carboxylate (NBHE) (the first monomer unit (1)), maleimide (MI) (the third monomer unit (3)) at weight ratio of 49/25/26, respectively, were dissolved in a flask containing 30 g of ethyl lactate. Subsequently, 2.1g dimethyl-2, 2′-azobis(2-methyl propionate) (V-601 made by Wako Pure Chemical Industries) along with approximately 2 ml of ethyl lactate were added in the flask as polymerization initiator. The monomer mixture was drop fed into the heated solvent at 70° C. drop by drop under magnetic stirring. The feeding rate was 9.62 μl/s. After about 1.5 hours, the drop feeding of the monomer solution was completed. Stirring at 70° C. was maintained for another 2 hours to complete the reaction.

Additional samples) of copolymer (16) were prepared in a similar procedure as above, with the exception that the solvent was heated to 90° C. and 99° C., respectively. In addition, in synthesis, the initial solvent flask included 29 g of ethyl lactate, the monomer mixture included 16 g of solvent, and the polymerization initiator solution included 15 g of ethyl lactate. As a feeding rate of 9.62 μl/s, drop feeding of the monomer mixture in the sample was complete in 1.3 hours.

### Synthesis of Copolymer (18)

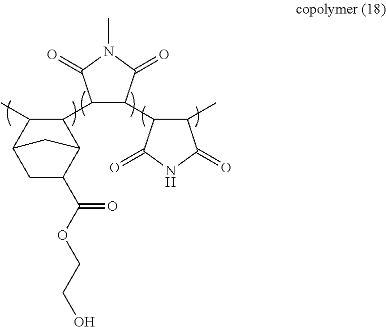

14.5 grams of gamma butyrolactone (GBL) (as solvent) and a magnetic bar were added into a 200 ml 3-neck round bottom flask reactor. The solvent was heated and maintained at 99° C. 15 grams total of monomers of n-methylmaleimide (NMMI) (the second monomer unit (2)), 2-hydroxyethyl bicyclo[2.2.1]hept-5-ene-2-carboxylate (NBHE) (the first monomer unit (1)), and maleimide (MI) (the third monomer unit (3)) at weight ratio of 49/25/26, respectively, were dissolved according to the desired monomer weight ratio in 18g GBL. In a separate vial, 2.1g dimethyl-2, 2′-azobis(2-methyl propionate) (V-601 made by Wako Pure Chemical Industries) was dissolved in 6 g GBL as polymerization initiator solution. Subsequently, the monomer mixture and initiator solution in ice bath were drop fed separately into the reactor using a Hamilton syringe pump. The feeding speed was 250 μl/40 s for the monomer mixture and 250 μl/160 s for the initiator solution, respectively. After consuming all mixture solutions in ˜1.5 hours, the temperature was maintained at 99° C. for another 2 hours to allow the reaction to be completed. The heat was then removed and the reactor was cooled down to room temperature.

Photoimageable compositions in accordance with the invention were evaluated based on the following three protocols:
1) Solvent Stripping to determine crosslinking temperature;
2) Developer solubility to determine if the photoactive agent inhibits solubility; and
3) Photoimageable to determine if the exposed region of the polymer layer can be developed with a developer solution.

### Solvent Stripping to Determine Crosslinking Temperature.

Various samples were prepared by admixing, in a solvent, a diluted binder polymer solution (e.g., 10-20% of the copolymer) and an organometallic compound. The resulting compositions were then spin coated onto a silicone substrate to form a thin layer of the polymer. The substrate and polymer layer were then subjected to heating over a temperature range to determine the temperature at which crosslinking occurs. At each temperature stage, the substrate and polymer layer were dipped into a solvent stripping bath for 60 seconds. Once cured, the thickness of the polymer layer should not decrease when subjected to solvent stripping. The temperature after which none of the polymer layer is removed (no appreciable change in thickness) is considered sufficient to result in curing of the polymer layer.

Table 1 summarizes the compositions tested and the temperature at which the binder polymer is crosslinked. The samples prepared in Table 1 did not include a photoactive compound (PAC).

TABLE 1
EVALUATION OF CROSSLINKING TEMPERATURES

| | | | | | Cross-linking |
|---|---|---|---|---|---|
| Sample | | | | Solvent | Temperatures |
| No. | Binder Polymer | Organo Metal Compound | PAC | Stripping | (° C.) |
| 1 | Copolymer (1) | Bis(cyclopentadienyl) | — | PGMEA* | 130 |
| | | zirconium (IV) | | | |
| 2 | Copolymer (3) | Bis(cyclopentadienyl) | — | PGMEA | 150 |
| | | zirconium (IV) | | | |
| 3 | Copolymer (3) | Bis(2,4- | — | PGMEA | >170 |
| | | pentanedionato) | | | |
| | | cobalt | | | |
| 4 | Copolymer (15) | Bis(2,4- | — | Ethyl Acetate | 170 |
| | | pentanedionato) | | | |
| | | cobalt | | | |
| 5 | Copolymer (15) | Bis(2,4- | — | Ethyl Acetate | 170 |
| | | pentanedionato) | | | |
| | | nickel | | | |
| 6 | Copolymer (9) | Bis(2,4- | — | Ethyl Acetate | 170 |
| | | pentanedionato) | | | |
| | | cobalt | | | |
| 7 | Copolymer (9) | Bis(2,4- | — | Ethyl Acetate | 170 |
| | | pentanedionato) | | | |
| | | nickel | | | |
| 8 | Copolymer (16) | Bis(2,4- | — | Ethyl lactate | 170 |
| | | pentanedionato) | | | |
| | | cobalt | | | |
| 9 | Copolymer (17) | Dibutoxy Bis(2,4- | — | HBM** | 240 |
| | | pentanedionato) | | | |
| | | zirconium | | | |
| 10 | Copolymer (18) | Zirconium n-butoxide | — | HBM | 240 |

*propylene glycol methyl ether acetate
**2-hydroxyisobutyric acid methyl ester

In the above table, 10 different samples were prepared having an organometallic content ranging from all 8 to 18 weight %.

### Developer Solubility

In the following experiments, the effect of the photoactive compound (PAC) of solubility of the polymer layer when exposed to a developer solution. In the absence of exposure, the PAC should inhibit the developer from solubilizing the polymer layer.

Various samples were prepared by admixing, in a solvent, copolymers in accordance with the invention, an organometallic compound, and a PAC. The photoimageable compositions included 17 weight percent PAC (formulas I and II were used in this trial) and 12 weight percent as the organometal compound (bis(cyclopentadienyl) zirconium (IV) dichloride) to binder polymer. The resulting solution was then spin coated as a layer and baked at 90° C. to remove solvent. Thereafter, the thickness of the polymer layer was measured, and the polymer layer was immersed in a developer (tetramethyl ammonium hydroxide (TMAH)) for 60 seconds. The thickness of the layer was then measured and compared to an identical composition that did not include a PAC. Ideally, formulations with PAC should be intact with minimal, if any, dissolving of the polymer binder layer. Formulations without PAC should be mostly or completely dissolved. The results are summarized in Table 2 below.

TABLE 2
Effect of PAC on Polymer Binder Solubility

| Sample | | Monomer Content | Did PAC inhibit |
|---|---|---|---|
| No. | Copolymer | x/y or x/y/z | developer solubility |
| 11 | Copolymer (1) | 20/80 | No |
| 12 | Copolymer (1) | 15/85 | Yes |
| 13 | Copolymer (1) | 17.5/82.5 | Yes |
| 14 | Copolymer (2) | 20/80 | No |
| 15 | Copolymer (15) | 20/55/25 | Yes |
| 16 | Copolymer (10) | 20/45/35 | Yes |
| 17 | Copolymer (19) | 49/25/26 | Yes |
| 18 | Copolymer (20) | 54/20/26 | No |
| 19 | Copolymer (16) | 48~51/25/24~27 | No |
| 20 | Copolymer (18) | 46/28/26 | No |
| 21 | Copolymer (17) | 52/28/20 | Yes |

From the above Table 2, it can be seen that by altering the relative amount of each component in the polymer binder, the solubility of the copolymer in the developer can be adjusted. For example, in Samples 11-13 the solubility of polymer binder in the developer was increased by increasing the proportion of the second monomer unit (2) in the copolymer. Similarly, the solubility of the other copolymers may be adjusted by changing the proportions of one or more of the first, second, or third monomer units ((1), (2), or (3)) relative to the other monomer units.

### Photoimageable

Various samples were prepared by admixing, in a solvent, a copolymer, PAC, and an organometallic compound. The resulting compositions were then spin coated onto a silicone substrate to form a thin polymer layer (from 1 to 2 μm thickness) of the photoimageable composition. The substrate and polymer layer were then prebaked to remove solvent. The layer was then exposed to I-line radiation (365 nm) using a photomask with a hole array (2 μm diameter). After exposure, the polymer layer was immersed in the developer (TMAH) for 30 to 60 seconds. The developed samples were then evaluated with scanning electron microscope (SEM) to determine photoimageability of the composition.

After I-line exposure, the PAC and polymer binder become soluble. Accordingly, a contrast between exposed regions and unexposed regions should be visible on the SEM.

Table 3 summarizes results for several samples that were tested.

TABLE 3
Results of Photoimageability Evaluation

| | | Monomer Content | Amount of | |
|---|---|---|---|---|
| Sample | | (1)/(2) or | PAC | Photo- |
| No. | Copolymer | (1)/(2)/(3) | (%) | imageable |
| 22 | Copolymer (1) | 20/80 | 17 | Yes |
| 23 | Copolymer (3) | 20/80 | 8* | No |
| 24 | Copolymer (15) | 20/55/25 | 17 | Yes |
| 25 | Copolymer (16) | 48~51/25/24~27 | 17 | Yes |

*A sample having 17 weight % PAC was not evaluated.

### Thermal Stability

The thermal stability of various copolymers in accordance with the present invention was also evaluated. In a first study, the effect of various monomers on the glass transition temperature of the copolymer was evaluated. Glass transition temperature was determined with differential scanning calorimetry (DSC). The results are summarized in Table 4 below.

TABLE 4
DSC Results

| | | Monomer Content | |
|---|---|---|---|
| Sample | | (1)/(2) or | T_{g} |
| No. | Copolymer | (1)/(2)/(3) | (° C.) |
| 26 | Copolymer (1) | 20/80 | 99 |
| 27 | Copolymer (15) | 55/20/25 | 160 |
| 28 | Copolymer (16) | 49/20/26 | 266 |
| 29 | Copolymer (20) | 44/20/26 | 220 |

From Table 4, it can be seen that the glass transition temperature of the polymer binder can be adjusted based on the selection of each monomer unit for monomer units (1), (2), and (3). In particular, Sample 26 had a glass transition temperature (T_{g}) of 99° C., whereas Sample 27, which include maleimide as a third monomer unit (3) had a glass transition temperature of 160° C. Similarly, Samples 28 and 29 both exhibited glass transition temperatures in excess of 200° C., which resulted, in part, from the specific monomers selected for the first and second monomer units of the copolymer. Thus, it can be seen that copolymers can be prepared that exhibit a wide range of glass transition temperatures from the selection of each of the first, second and third monomer units (1), (2), or (3).

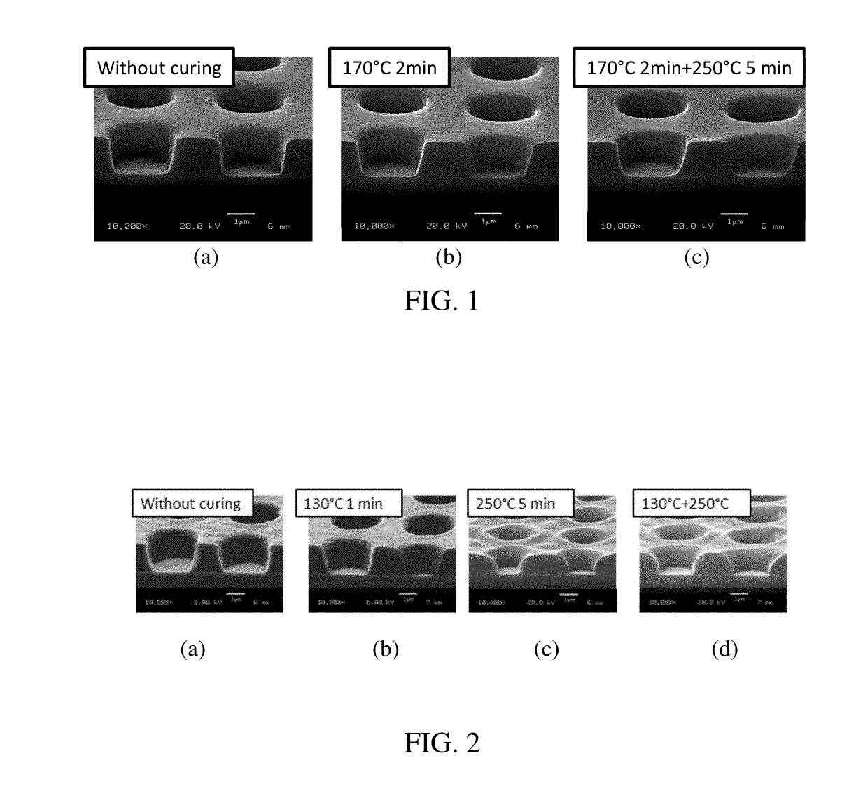

The thermal stability of Sample 25 at 250° C. was also evaluated. In this evaluation, a polymer layer comprising the photoimageable composition of Sample 25 (copolymer (16)) was exposed to I-line radiation with a photomask, and then developed to produce an array of holes in the polymer layer. Three SEM images were then taken are shown in FIG. 1. The first SEM image (a) is of the polymer layer prior to curing. The second SEM image (b) is of the polymer layer following a 2 minute curing bake at 170° C., and the third SEM image (c) is of the cured polymer layer that was then heated to 250° C. for 5 minutes.

From the SEM images of FIG. 1, it can be seen that the polymer layer prepared from Sample 25 exhibits good thermal stability as 250° C. as evident by the cross section profile of the holes, which remain intact following heating. In contrast, FIG. 2 provides four SEM images for a polymer layer prepared from Sample 22 (copolymer 1). SEM image (a) is of the polymer layer prior to curing. The second SEM image (b) is of the polymer layer following a 1 minute bake at 170° C., the third SEM image (c) is of the polymer layer that was heated to 250° C. for 5 minutes, and the third SEM image (d) is of the polymer layer that was first baked for 1 minute at 130° C., and then heated to 250° C.

As can be seen in the images, the polymer layer comprising copolymer (1) showed poor thermal stability at 250° C. as evident by the lateral flow of the polymer layer during baking.

### Hole Residue

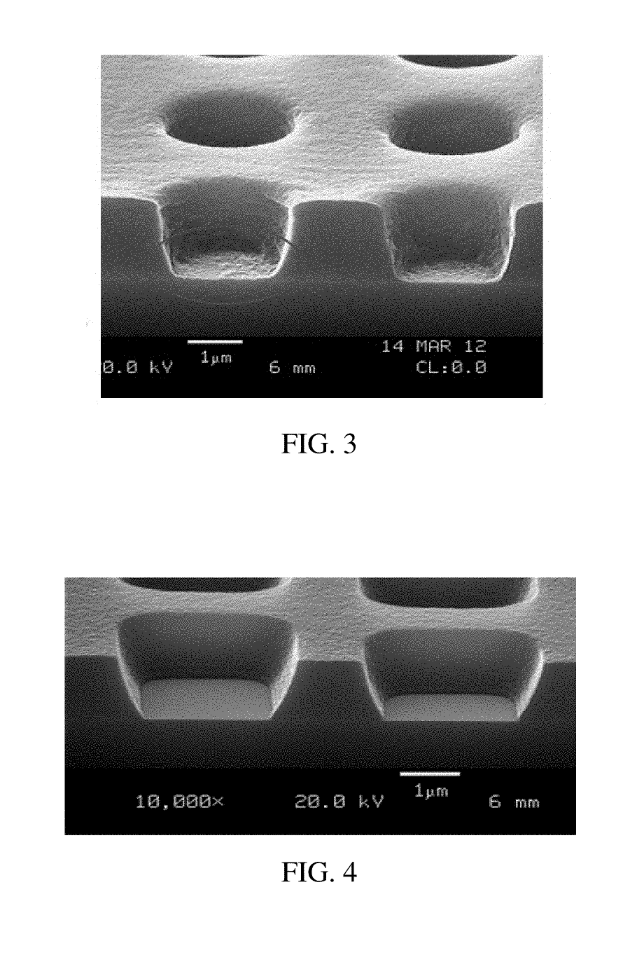

In some of the samples, a residue or scum was observed as being present in the base on the holes in the developed polymer layer as can be seen in FIG. 3. The polymer layer in FIG. 3 was prepared from a photoimageable composition comprising copolymer (16) as the binder polymer, 20 weight % PAC (6-Diazo-5,6-dihydro-5-oxo-1-naphthalene sulfonic acid ester of 4, 4′42-hydroxyphenyl)methylene]-bis92,3,5-thremethyl phenol (Formula II)), and 10 weight % bis(cyclopentadienyl) zirconium (IV) dichloride. The components were admixed in ethyl lactate as solvent to prepare the solution. The solution also contained 1 weight % of an organomodified polymethylsiloxane copolymer as a surfactant.

The solution of the photoimageable composition was solution cast onto a

Si substrate and then prebaked, exposed to I-line radiation (dosage of 96 mJ/cm²) with a photomask array having 2 μm round holes, and then cured by heating to 250° C. on a hot plate. As can be seen in the SEM image of FIG. 3, the developed holes include a residue or “scum” that is insoluble to the developer and remains on the surface of the substrate following development.

To address this issue, it has been discovered that the addition of a developer soluble additive can remove this so-called “scum.” FIG. 4 is an SEM image of a developed polymer layer to which 0.1 weight % of a polyalkylene glycol based copolymer has been added. In this example, the additive is available from Dow Chemicals under the trade name UCON™. The polymer layer in FIG. 4 is identical to that described above for FIG. 3, with the exception of the inclusion of the additive and the I-line dosage was 45 mJ/cm². In FIG. 4, it can be seen that the inclusion of the additive results in the removal of the residue from the base of the hole.

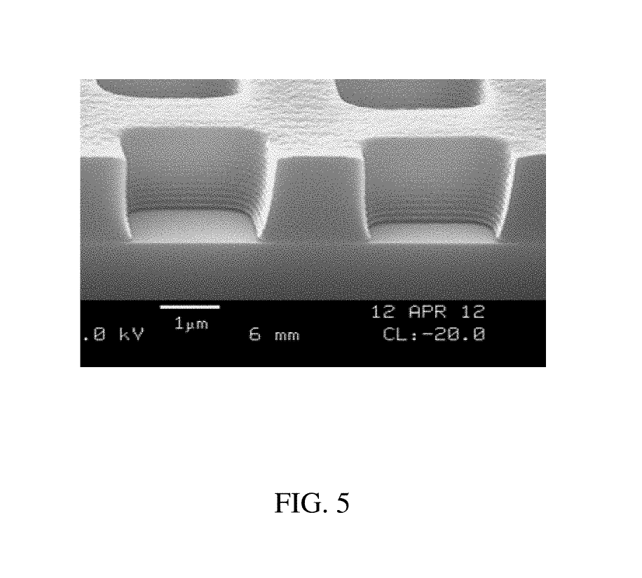

It has also been discovered that the issue of hole residue can be addressed using a polymeric hybrid PAC. FIG. 5 is an SEM image of a developed polymer layer to which 12 weight % of a PAC comprising a polymeric hybrid of 6-Diazo-5,6-dihydro-5-oxo-1-naphthalene sulfonic acid ester of 4, 4′-[2-hydroxyphenyl)methylene]-bis92,3,5-thremethyl phenol (Formula II) has been added. The structure of the polymeric hybrid is shown in formula (V) above. The dosage of the I-line radiation dosage was 170 mJ/cm². As in the polymer layer shown in FIG. 4, the use of the PAC-polymer hybrid effectively removed any residue during development.

1. A photoimageable composition for preparing a crosslinked film comprising
a copolymer having at least a first monomer unit and a second monomer unit, distinct from said first monomer unit, wherein the first monomer unit comprises one or more of a carboxyl or hydroxyl group;
a photoactive compound; and
an organometallic compound.

2. The composition of claim 1, wherein the first monomer unit comprises a norborene or acrylate residue.

3. The composition of claim 1, wherein the second monomer unit is a residue of a vinyl monomer having a phenyl, benzyl, or benzocyclobutene moiety, a residue of a substituted acrylate monomer having a benzyl moiety, a phenyl moiety, or an ether benzocyclobutene moiety, a residue of a styrene monomer, or a residue from a norborene monomer having a benzocyclobutene ester moiety.

4. The composition of claim 1, wherein the first monomer unit is selected from the group consisting of 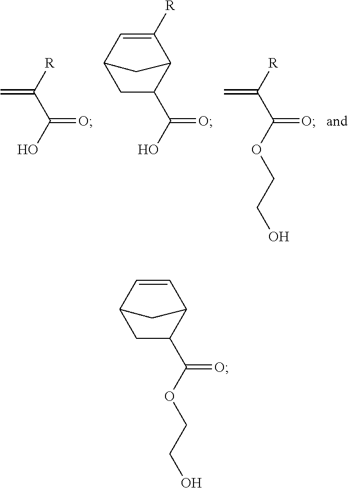
and the second monomer unit is selected from the group consisting of 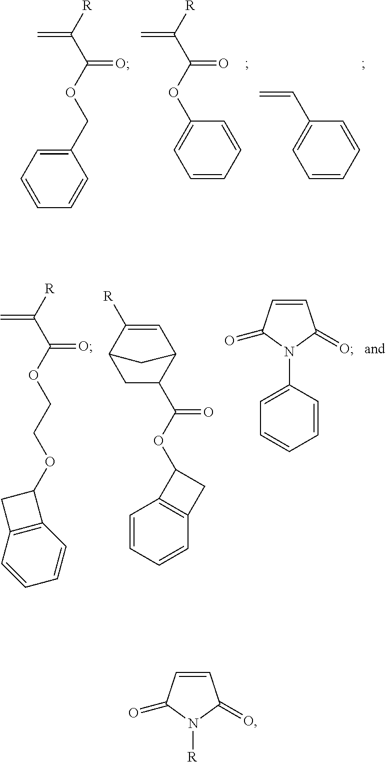
wherein R is a methyl group, hydrogen or deuterium, and the amount of the first monomer unit is between 8 and 40 weight percent, and the amount of the second monomer unit is between 60 and 92 weight percent.

5. The composition of claim 1, wherein monomer unit (1) comprises a residue of one or more of methacrylate and hydroxyethyl methacrylate, and monomer unit (2) comprises a residue of one or more of benzyl methacrylate, styrene, a substituted norborene, and an n-substituted maleimide.

6. The composition of claim 1, further comprising a monomer unit (3) comprising a residue of a maleimide.

7. The composition of claim 1, wherein the organometallic compound is selected from the group consisting of:
compounds having the following formula (A): 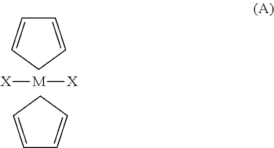
wherein M is a metal atom selected from the group consisting of Sc, Ti, V, Cr, Mn, Fe, Co, Ni, Cu, Zn, Zr, Nb, Mo, Tc, Ru, Rh, Pd, Ag, and Cd;
X is a halogen or OR, wherein R is a C₁-C₈ linear, branched, cyclic alkyl, or substituted alkyl group;
compounds having the following formulas (B) and (C): 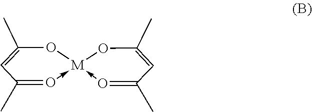
wherein M is a metal atom selected from the group consisting of Sc, Ti, V, Cr, Mn, Fe, Co, Ni, Cu, Zn, Zr, Nb, Hf, Mo, Tc, Ru, Rh, Pd, Ag, and Cd; 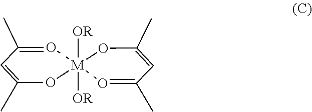
wherein M is a metal atom selected from the group consisting of Sc, Ti, V, Cr, Mn, Fe, Co, Ni, Cu, Zn, Zr, Nb, Hf, Mo, Tc, Ru, Rh, Pd, Ag, and Cd, and R is C₁-C₆ alkyl group; and
metallic alkoxy compounds having the following formula M(OC₁-C₄), where M is a metal atom selected from the group consisting of Sc, Ti, V, Cr, Mn, Fe, Co, Ni, Cu, Zn, Zr, Nb, Hf, Mo, Tc, Ru, Rh, Pd, Ag, and Cd.

8. The composition of claim 1, wherein the photoactive compound is selected from the group consisting of 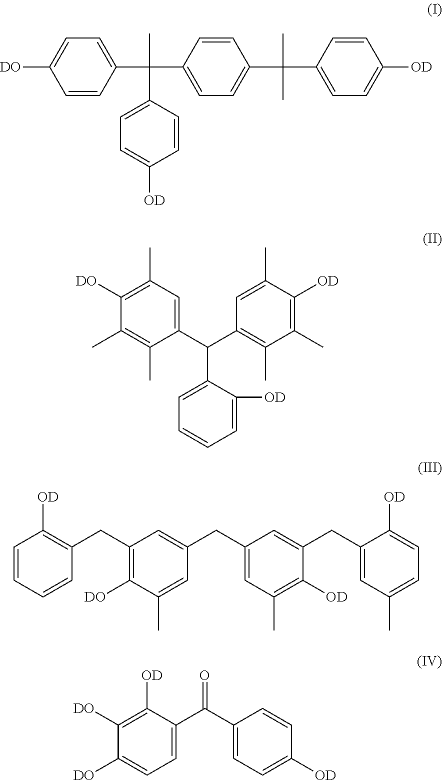
wherein D is a hydrogen atom, a deuterium atom, or a compound having the following formula: 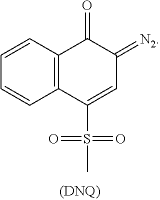
and
a polymeric material selected from the group consisting of 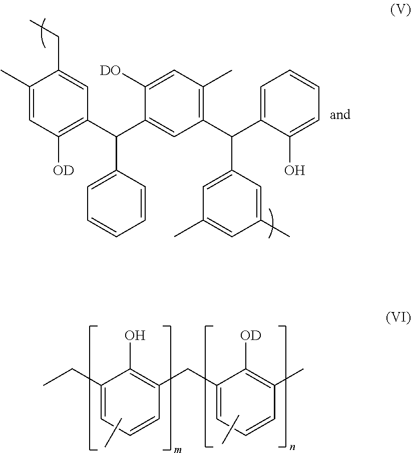
wherein D is a hydrogen atom, a deuterium atom, or a compound having the following formula:

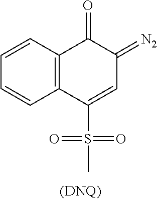

9. The composition of claim 1, further comprising an additive selected from the group consisting of organomodified polymethylsiloxane, polyalkylene glycol based copolymers, and fluorosurfactants.

10. The composition of claim 1, wherein the amount of the photoactive compound is from 8 to 22 weight percent, based on the total weight of the composition, and the amount of organometallic compound is from 10 to 20 weight percent, based on the total weight of the solid content in the composition.

11. The composition of claim 1, wherein the copolymer optionally includes a third monomer unit comprised of a residue of a maleimide monomer, and wherein the copolymer is selected from the group consisting of 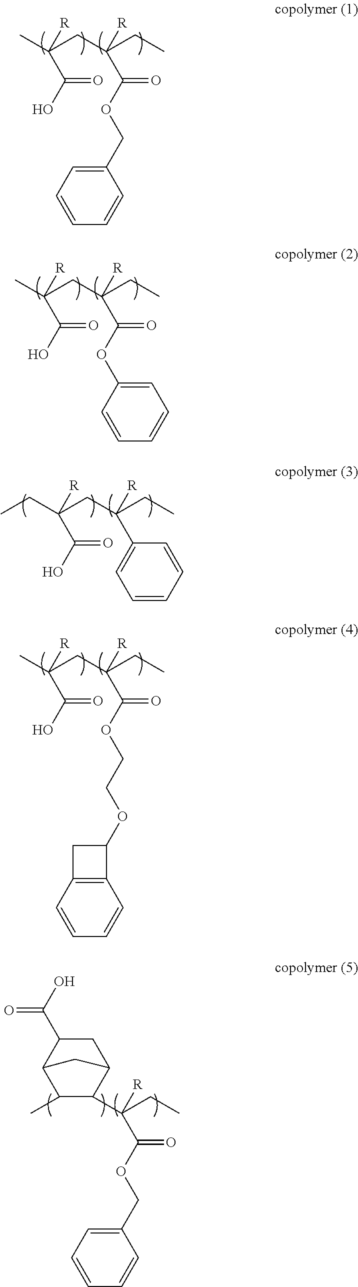 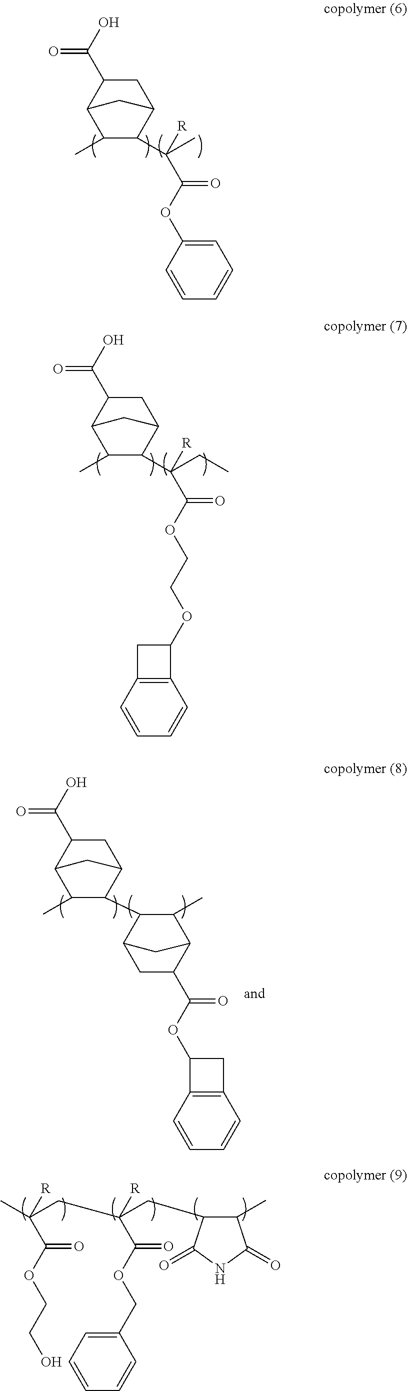 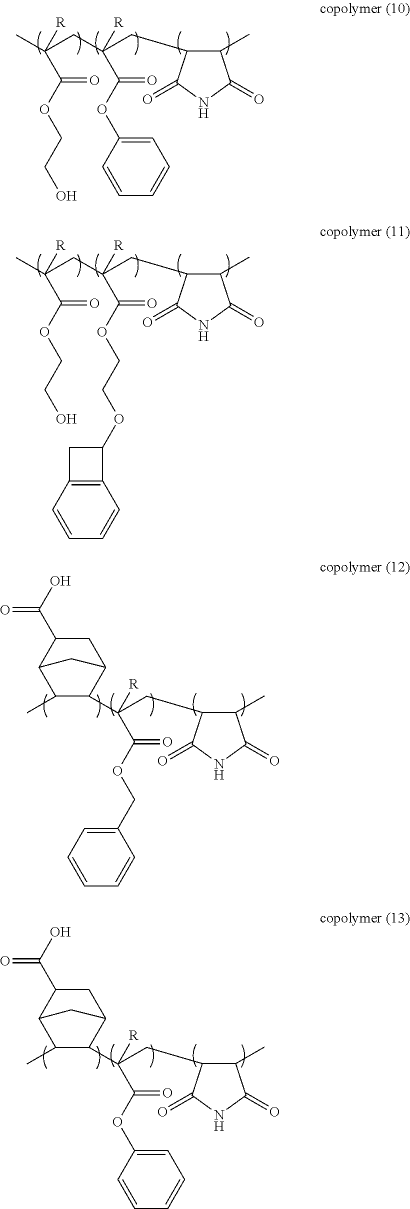 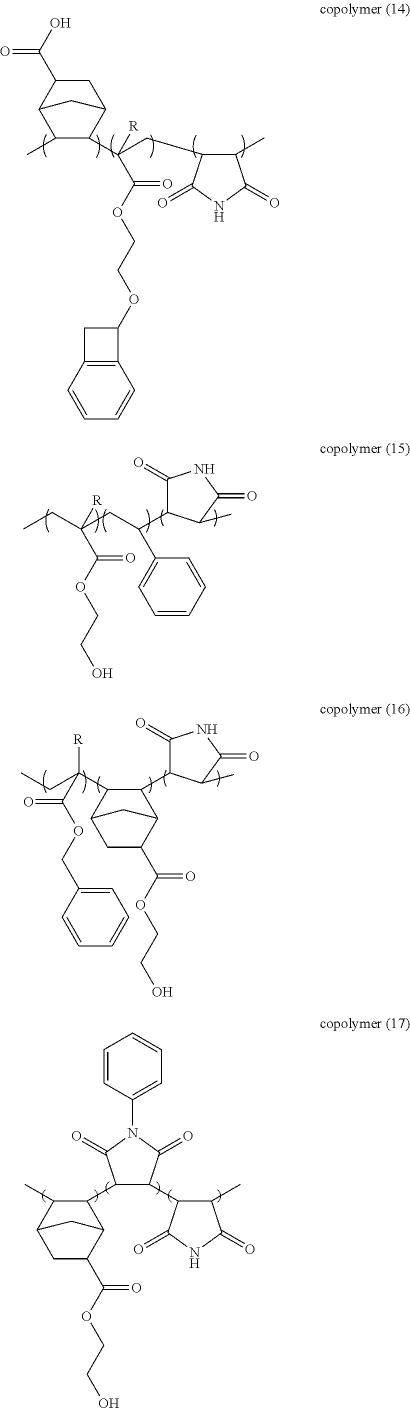 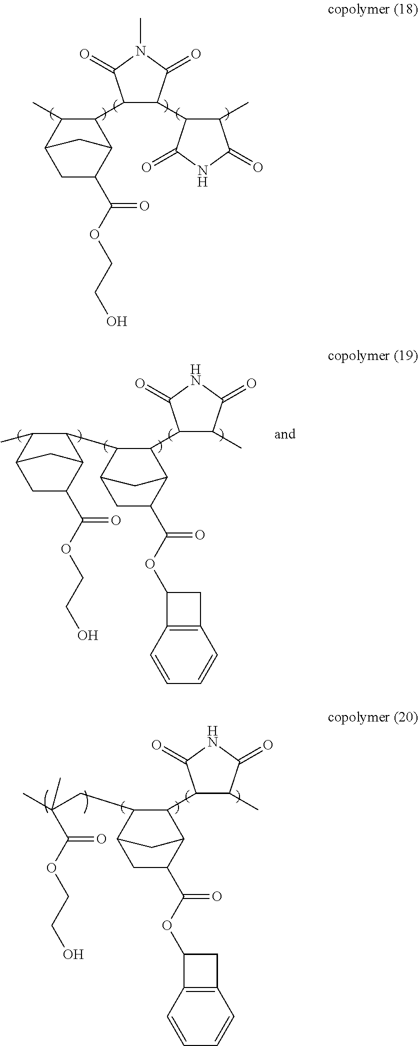
wherein R is hydrogen, deuterium, or a C₁-C₆ alkyl group, and wherein the amount of first monomer unit is between 8 and 40 weight percent, based on the total weight percent of the copolymer, the amount of the second monomer unit is between 60 and 92 weight percent, based on the total weight percent of the copolymer, and when present, the amount of the third monomer unit is between 16 and 40 weight percent.

12. A polymer binder comprising a network of crosslinked chains of a copolymer having a first monomer unit comprising one or more of a carboxyl or hydroxyl groups and a second monomer unit that is distinct from the first monomer unit, and wherein the carboxyl or hydroxyl groups of the first monomer unit are crosslinked to each other via an organometallic compound to define said network.

13. The polymer binder of claim 1, further comprising a third monomer unit comprised of a residue of a maleimide monomer, and wherein the first monomer unit (1) comprises a norborene or acrylate residue, and the second monomer unit (2) is a residue of a vinyl monomer having a phenyl, benzyl, or benzocyclobutene moiety, a residue of a substituted acrylate monomer having a benzyl moiety, a phenyl moiety, or an ether benzocyclobutene moiety, a residue of a styrene monomer, or a residue from a norborene monomer having a benzocyclobutene ester moiety.

14. The polymer binder of claim 13, wherein the amount of monomer unit (1) is between 8 and 40 weight percent, the amount of monomer unit (2) is between 60 and 92 weight percent, and the amount of monomer unit (3) is between 16 and 40 weight percent.

15. An electronic device comprising a film layer comprising the polymeric binder of claim 12.

16. An organic light emitting diode comprising the polymer binder of claim 12.

17. A method of preparing a pixel-defining layer comprising the steps of providing a substrate;
forming a plurality of electrodes on said substrate;
coating a layer of a photoimageable composition on said substrate overlying said electrodes, wherein said photoimageable composition comprises a copolymer having at least a first monomer unit and a second monomer unit, distinct from said first monomer unit, wherein the first monomer unit comprises one or more of a carboxyl or hydroxyl group, a photoactive compound, an organometallic compound, and a solvent;
prebaking said substrate with said layer of said photoimageable composition to remove the solvent;
exposing said substrate to masked radiation;
developing said substrate to form a desired pattern on the layer of said
photoimageable composition; and
baking said substrate with patterned pixel-defining layer at a temperature sufficient to crosslink said carboxyl or hydroxyl groups of the first monomer unit via said organometallic compound to form said pixel-defining layer.

18. The method of claim 17, further comprising depositing one or more organic layers within said pattern pixel, and a cathode material overlying said one or more organic layers to form an organic light emitting diode.

19. The method of claim 17, wherein the step of baking the substrate is performed at a temperature ranging from 150 to 260° C.

20. The method of claim 17, wherein the step of exposing the substrate radiation comprises exposure to I-line radiation.
